(19) United States
(12) Patent Application Publication
(10) Pub. No.: US 2025/0309063 A1
(43) Pub. Date: Oct. 2, 2025

(54) SHAPED DIE FOR SEMICONDUCTOR PACKAGES

(71) Applicant: TEXAS INSTRUMENTS INCORPORATED, DALLAS, TX (US)

(72) Inventors: YOU CHYE HOW, MELAKA (MY); HUAY YANN TAY, MELAKA (ML); WEI LI JULIEN MOK, MELAKA (MY)

(21) Appl. No.: 18/621,642

(22) Filed: Mar. 29, 2024

(51) Int. Cl. H01L 23/495; H01L 21/56; H01L 23/00

(52) U.S. Cl. CPC H01L 23/49513; H01L 21/561; H01L 21/565; H01L 24/32; H01L 24/48; H01L 24/96; H01L 24/97; H01L 24/29; H01L 2224/2919; H01L 2224/32245; H01L 2224/48249; H01L 2224/95001; H01L 2224/96; H01L 2224/97; H01L 2924/182

(57) ABSTRACT

The first example is related to a device including a die attach pad and a die. The die attach pad has a surface region. The die includes a base surface that fits within the surface region of the die attach pad. The die also includes a top surface opposite the base surface. The top surface is larger than the base surface.

### TECHNICAL FIELD

This description relates to semiconductor packages with a die shaped to have smaller base surface than top surface.

### BACKGROUND

A vast array of electronic devices, such as cellular phones, digital cameras, and music players, are packing more integrated circuits into an ever-shrinking physical space with expectations for decreasing cost. Integrated circuits used in the variety of electronic devices are typically manufactured on a semiconductor wafer. For example, dies of the semiconductor wafer are processed and packaged and then affixed to a die attach pad of an interconnect. However, devices in the same package group can have various dies with different dimensions. Accordingly, a corresponding variety of interconnects having die attach pads with various dimensions are maintained in inventory to accommodate the various dies.

### SUMMARY

A first example is related to a device including a die attach pad and a die. The die attach pad has a surface region. The die includes a base surface that fits within the surface region of the die attach pad. The die also includes a top surface opposite the base surface. The top surface is larger than the base surface.

A second example is related to a method of forming an integrated circuit (IC) package. The method includes providing a semiconductor wafer having a first surface and a second surface opposite the first surface. The method also includes etching a number of voids in the first surface of the semiconductor wafer to a first depth. The method further includes affixing the first surface of the semiconductor wafer to dicing tape. The method yet further includes dicing the semiconductor wafer to form a plurality of dies. The die of the plurality of dies has a base surface and a top surface opposite the base surface. The top surface has a larger surface area than the base surface. The method includes mounting the dies to die attach pads. The method also includes singulating the mounted dies.

A third example is related to an IC package. The IC package includes a die attach pad having a surface region. The IC package also includes a lead separated from the die attach pad. The IC package further includes a die having a base surface that fits within the surface region of the die attach pad and a top surface opposite the base surface. The top surface is larger than the base surface. The IC package yet further includes a bond wire attached at the die and the lead. The IC package includes a molding compound that encapsulates the bond wire, the lead, the die, and the die attach pad.

### BRIEF DESCRIPTION OF THE DRAWINGS

FIG. 1A illustrates a cross-sectional view of an example of a semiconductor device having a shaped die.

FIG. 1B illustrates a top-down view of the example of the semiconductor device of FIG. 1A.

FIG. 1C illustrates a cross-sectional view of an alternative example of a semiconductor device having a shaped die.

FIG. 2A illustrates one example of a shaped die having a T-shape.

FIG. 2B illustrates another example of a shaped die having a trapezoidal shape.

FIG. 3 is a flowchart illustrating an example method for forming a semiconductor device including a shaped die.

FIG. 4 illustrates an example of a first stage of a method for forming the semiconductor device.

FIG. 5 illustrates an example of a second stage of the method for forming the semiconductor device.

FIG. 6 illustrates an example of a third stage of the method for forming the semiconductor device.

FIG. 7 illustrates an example of a fourth stage of the method for forming the semiconductor device.

FIG. 8 illustrates an example of a fifth stage of the method for forming the semiconductor device.

FIG. 9 illustrates an example of a sixth stage of the method for forming the semiconductor device.

FIG. 10 illustrates an example of a seventh stage of the method for forming the semiconductor device.

FIG. 11 illustrates an example of an eighth stage of the method for forming the semiconductor device.

FIG. 12 illustrates an example of a ninth stage of the method for forming the semiconductor device.

FIG. 13 illustrates an example of a tenth stage of the method for forming the semiconductor device.

FIG. 14 illustrates an example of an eleventh stage of the method for forming the semiconductor device.

### DETAILED DESCRIPTION

Semiconductor devices include multiple semiconductor components, such as semiconductor dies. Various interconnects are kept in inventory to accommodate the variety in the dimensions of dies. For example, some dies in a package group have smaller dimensions that are accommodated by a first interconnect having a smaller die attach pad, while other dies of the package group have larger dimensions that are accommodated by a second interconnect having a larger die attach pad. Given the push for miniaturization of electronic devices, the first interconnect is kept in inventory to create a smaller device footprint and the second interconnect is kept in inventory to accommodate the dies with a larger footprint. Having different interconnects in inventory, complicates fabrication and reduces interconnect sharing and consolidation within and across package groups.

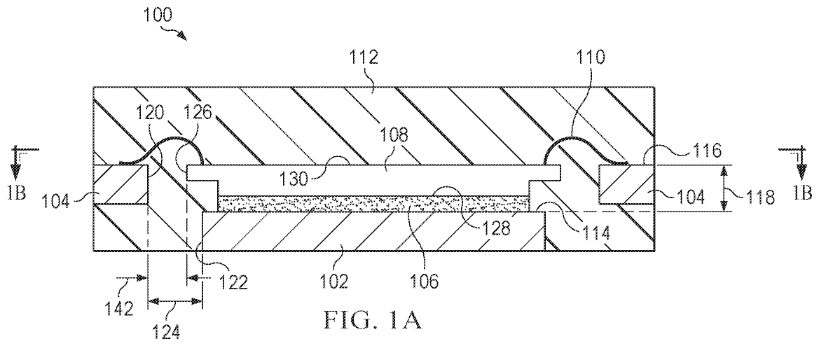

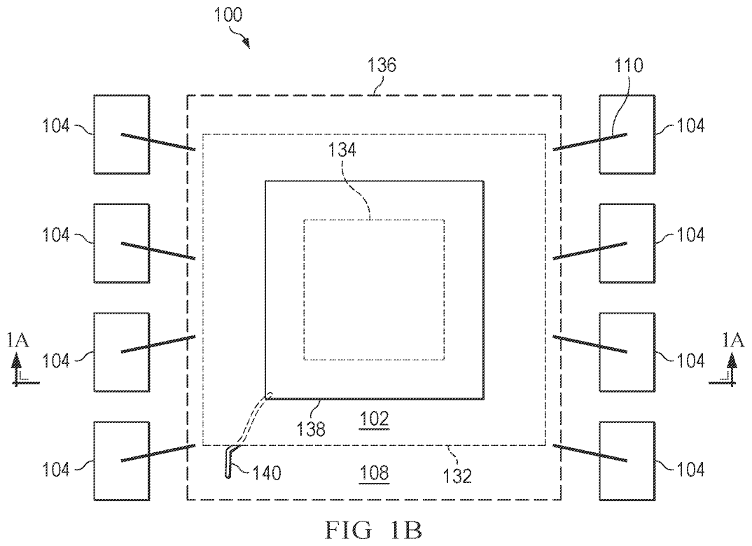

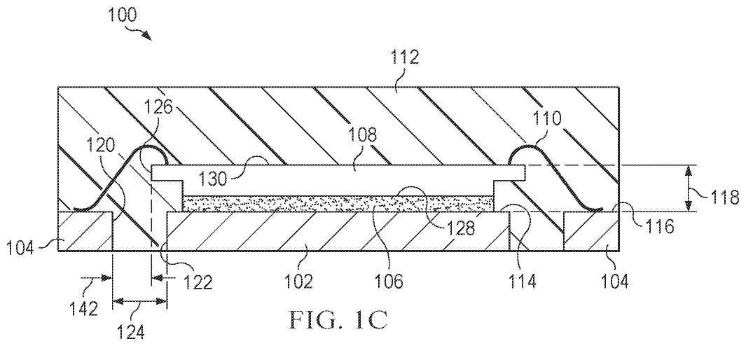

In the semiconductor devices and methods described herein, the die is shaped to create a base surface having smaller die footprint so that the shaped die is able to be mounted to the smaller die attach pad of an interconnect. For example, plasma etching is used to etch the die to have a base surface that fits within the surface region of the die attach pad. A top surface of the die, opposite the base surface, has a larger surface area then the base surface area. The size of the die can increase by approximately sixty-five percent and still fit in an interconnect with a smaller die attach pad. Continuing the example from above, the shaped die is accommodated by the first interconnect, rather than requiring a second interconnect even if the top surface is larger than the die attach pad of the first interconnect. Accordingly, the shaped die encourages interconnect sharing, reduces inventory complexity, and simplifies fabrication of the semiconductor devices, thereby reducing manufacturing costs. FIG. 1A illustrates a cross-sectional view of an example of a

semiconductor device having a shaped die. The semiconductor device 100 includes a die attach pad 102 and a number of lead(s) 104 formed from an interconnect. The interconnect is formed of an electrically conductive material, such as copper, palladium, gold, silver, or other appropriate conductive metal or metal alloy with similar properties. For example, the interconnect is formed from a copper sheet.

A bond layer 106 bonds a die 108 to the die attach pad 102. The bond layer 106 is, for example, a filmy adhesive agent, such as an epoxy resin. A bond wire 110 is attached at the die 108 and the lead 104 and forms an electrical connection between the die 108 and the lead 104. The die attach pad 102, lead(s) 104, bond layer 106, the die 108, and the bond wire(s) are at least partially encapsulated in a molding compound 112 to form a packaged semiconductor device 100, such as an integrated circuit (IC) or a system on chip (SOC). The molding compound 112 is formed of one or more insulating materials, such as organic resins (e.g., epoxy), inorganic resins, and/or other suitable materials.

In some examples, the interconnect includes angled portions separating horizontal sections corresponding to the die attach pad 102 and the lead(s) 104. For example, a first plane extends through and defines a surface region 114 of the die attach pad 102. A second plane extends through and defines a bonding surface 116 of the lead(s) 104. The first plane is approximately parallel to the second plane and separated by a vertical distance 118. The vertical distance 118 is caused by the angled portions of the interconnect. The die attach pad 102 is vertically lower than the lead(s) 104 by the vertical distance 118 such that the die attach pad 102 is inset relative to the lead(s) 104.

The lead(s) 104 are laterally separated from the die attach pad 102 by a gap distance 124. For example, a proximal lead edge 120 is a surface of the lead 104 that is proximate the die attach pad 102. A proximate pad edge 122 is a surface of the die attach pad 102 that is proximate the lead 104. The proximate pad edge 122 defines an edge plane that includes the surface of the die attach pad 102 that is proximate the lead 104. The proximal lead edge 120 is separated from the proximate pad edge 122 by the gap distance 124.

A die edge 126 of the die 108 separates a base surface 128 of the die 108 and the top surface 130 of the die 108. The die edge 126 is a surface of the die 108 that is proximate the lead(s) 104. The base surface 128 is affixed to the surface region 114 of the die attach pad 102. The top surface 130 is larger than the base surface 128 of the die 108. The die edge 126 extends to the edge plane of the proximate pad edge 122 or beyond the edge plane into the gap distance 124. Accordingly, the die edge 126 of the die 108 is as laterally close to the lead 104 as the die attach pad 102 or closer. Therefore, the top surface 130 of the die 108 extends to or beyond the edge plane.

Turning to FIG. 1B, the number of lead(s) 104 can be disposed around (e.g., circumscribe) the die attach pad 102. The bond wire 110 provides an electrical connection between the die 108 and a given lead 104. During packaging, the semiconductor device 100 is singulated such that the lead 104 forms a lead exposed to an external environment. The leads of the singulated semiconductor device 100 enable the die 108 to be electrically coupled with one or more other electrical components external to the semiconductor device 100.

The surface region 114 of the die attach pad 102 has a die attach pad perimeter 132. The base surface 128 of the die 108 fits within the die attach pad perimeter 132 of the surface region 114, whereas the top surface 130 of the die 108 extends past the die attach pad perimeter 132. For example, the base surface 128 has a base perimeter 134 and the top surface 130 has a top perimeter 136. The base perimeter 134 fits within the die attach pad perimeter 132. The top perimeter 136 overlays or extends beyond the die attach pad perimeter 132 in at least one direction. In some embodiments, a ground line 138 is embedded in the die attach pad 102. A ground wire 140 attaches at the die 108 and the ground line 138.

Returning to FIG. 1A, because the top perimeter 136 overlays or extends beyond the die attach pad perimeter 132 in at least one direction, the gap distance 124 is greater than a lead separation distance 142 defined by the distance between the proximal lead edge 120 of the lead 104 and the die edge 126 of the die 108. In some examples, the lead separation distance 142 varies between different lead(s) 104 based on the shape of the die. For example, the lead separation distance 142 may be approximately equal to the gap distance 124 for a first lead 104 but the lead separation distance 142 may less than the gap distance 124 for a second lead 104. FIG. 1C is an alternative example of semiconductor 100 in FIG. 1A in which the leads 104 are in the same plane as die attach pad 102. In this example a bottom surface of both leads 104 and die attach pad 102 are exposed on a bottom surface of die attach pad 102.

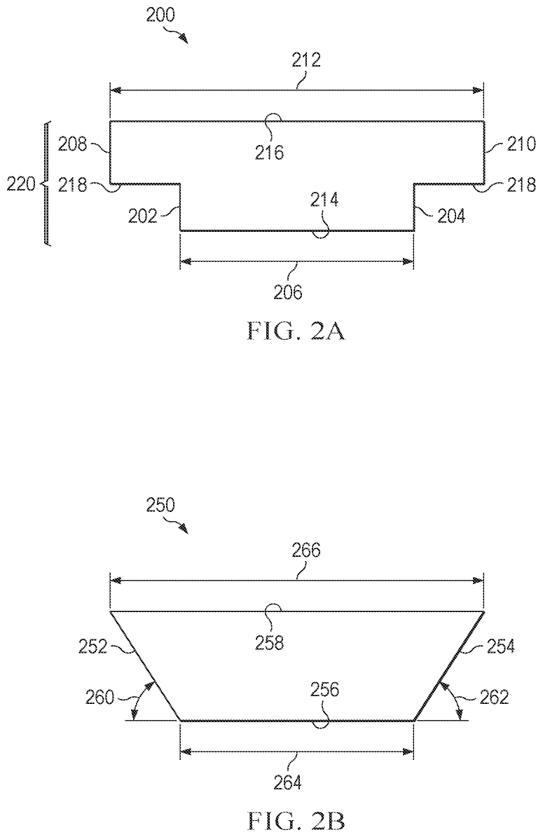

FIG. 2A illustrates one example of a shaped die 200 having a T-shape. For example, the die 200 includes a base portion and an overhang portion. The base portion includes a first base sidewall 202 opposing a second base sidewall 204 separated by a base width 206. The overhang portion includes a first overhang sidewall 208 opposing a second overhang sidewall 210 separated by an overhang width 212. The overhang width 212 is greater than the base width 206. Accordingly, a base surface 214 of the die 200 has a smaller surface area then the top surface 216 of the die 200.

The base sidewalls 202, 204 extend from the base surface 214 to an overhang surface 218. The overhang sidewall 208, 210 extends from the overhang surface 218 to the top surface 216 such that the die sidewalls are discontinuous. For example, the first die sidewall 220 that includes the first base sidewall 202 and the first overhang sidewall 208 is discontinuous at the overhang surface 218.

FIG. 2B illustrates another example of a shaped die 250 having a trapezoidal shape. The die 250 includes a first die sidewall 252 opposing a second die sidewall 254. The die sidewalls 252, 254 extend continuously at an angle from the base surface 256 to a top surface 258. The angle is relative to the surface region (e.g., the surface region 114 of FIG. 1A) of the die attach pad (e.g., the die attach pad 102 of FIG. 1A) is less than ninety degrees. For example, if the die 250 is affixed to the surface region of the die attach pad at the base surface 256, then the first die sidewall 252 forms a first angle 260 and the second die sidewall 254 forms a second angle 262. The angles 260, 262 form tapered die sidewalls 252, 254 such that the base surface 256 of the die 250 has a smaller surface area then the top surface 258 of the die 250. For example, the base width 264 of the die 250 is shorter than the upper width 266.

In examples in which the die attach pad (e.g., the die attach pad 102 of FIG. 1A) is inset such that the surface region (e.g., the surface region 114 of FIG. 1A) of the die attach pad (e.g., the die attach pad 102 of FIG. 1A) defines a first plane and the bonding surface (e.g., the bonding surface 116 of FIG. 1A) of the lead(s) (e.g., the lead(s) 104 of FIG. 1A) defines a second plane separated from the first plane by a vertical distance (e.g., the vertical distance 118 of FIG. 1A). The smaller surface area of the base surface (e.g., the base surface 128 of FIG. 1A, the base surface 214 of FIG. 2A, the base surface 256 of FIG. 2B) is affixed to a smaller surface region that is able to accommodate the base width (e.g., the base width 206 of FIG. 2A, the base width 264 of FIG. 2B), even though the larger width (e.g., the overhang width 212 of FIG. 2A, the upper width 266 of FIG. 2B) of the top surface (e.g., the top surface 130 of FIG. 1A, the top surface 216 of FIG. 2A, the top surface 258 of FIG. 2B) exceeds the smaller surface region. Accordingly, a smaller interconnect can be used to support the die even if the footprint of the die attach pad is smaller that the dimensions of the top surface of the die.

Furthermore, the die (e.g., the die 108 of FIG. 1A, the die 200 of FIG. 2A, the die of FIG. 2B) and the bond wire (e.g., the bond wire 110 of FIG. 1A) are supported. For example, the die attach pad provides mechanical support to the die because the die is affixed to the die attach pad by the bond layer (e.g., the bond layer 106 of FIG. 1A) even though dimension of the die exceed dimensions of the die attach pad. Additionally, because the leads define a second plane that is vertically higher than the die attach pad in some examples, the leads and the top surface of the die are closer in height. Accordingly, there is less vertical strain on the bond wire connecting the leads to the die.

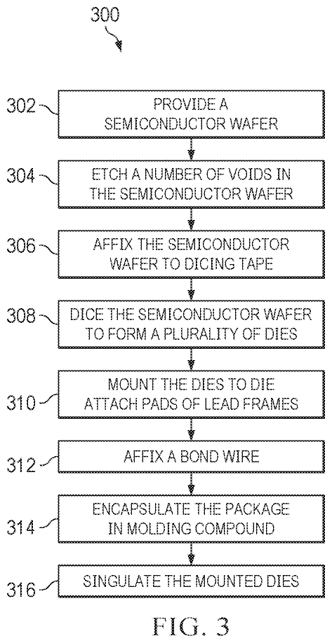

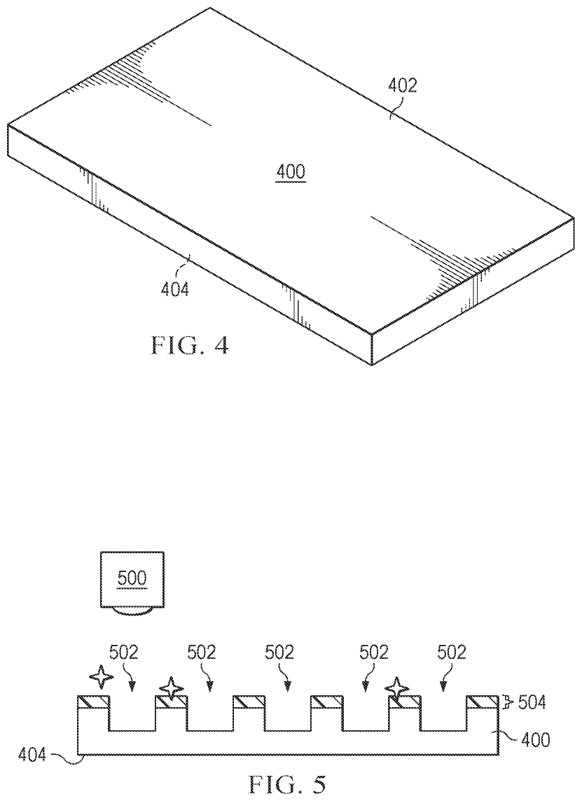

FIG. 3 illustrates a method 300 for formation of the semiconductor device, such as the semiconductor device 100 of FIG. 1A with a shaped die (e.g., the die 108 of FIG. 1A, the die 200 of FIG. 2A, the die of FIG. 2B). The method 300 of FIG. 3 will be described with respect to FIGS. 4-14, which illustrate examples of the semiconductor device 100 at different stages of fabrication. For purposes of simplification, FIGS. 4-14 employ the same reference numbers to denote the same structure.

At block 302, the method 300 includes providing a semiconductor. For example, FIG. 4 illustrates an example of a semiconductor wafer 400 having a first surface 402 opposite a second surface 404 provided in a first stage. The semiconductor wafer is a substrate, such as silicon, silicon carbide, or other suitable material, either in substantially pure form or in combination with additional materials. As another example, the semiconductor wafer 400 is a single crystal material, such as a single crystal silicon substrate. As yet another example, the semiconductor wafer 400 is a complementary metal-oxide semiconductor (CMOS) substrate and includes circuitry formed thereon. The formation of the semiconductor wafer 400 is dependent on the application of the semiconductor device (e.g., the semiconductor device 100 of FIG. 1A) being fabricated.

At block 304 of FIG. 3, the method 300 includes etching a number of voids in the first surface of the semiconductor wafer 400 to a first depth. As shown in the example of FIG. 5, in a second stage, a feature tool 500 removes wafer material from the first surface 402 of the semiconductor wafer 400 to form the voids 502. For example, the feature tool 500 is an etch apparatus laser, saw, etc. The voids 502 can have a variety of shapes. In some examples, the voids 502 have spaced apart sidewalls that extend toward the second surface 404 approximately orthogonally to the first surface 402 to form spaced apart die sidewalls (e.g. the first base sidewall 202 and the second base sidewall 204 of FIG. 2A). In other examples, the voids 502 can have tapered sidewalls to form the angled die sidewalls (e.g. tapered die sidewalls 252, 254 of FIG. 2B).

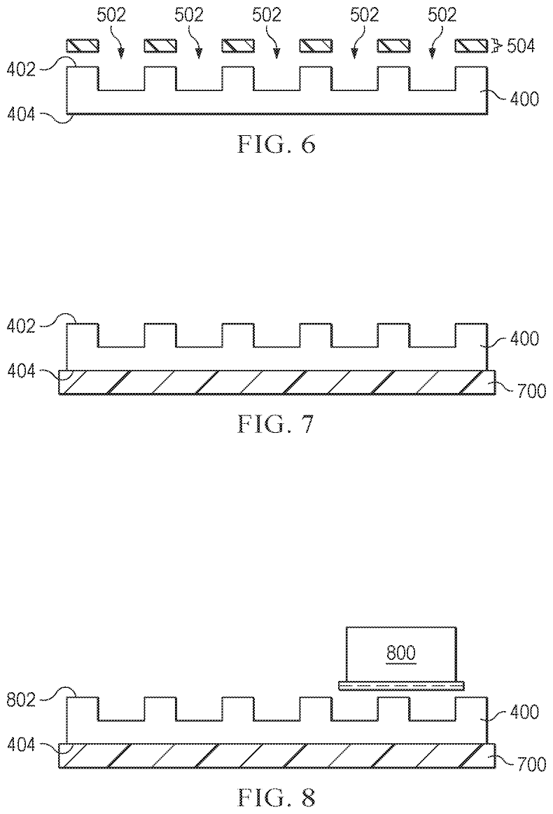

In some examples, a photoresist layer 504 is formed on the first surface 402 of the semiconductor wafer 400 and patterned by a performing selective irradiation. The irradiated or nonirradiated portions are removed by applying a developer material. For example, a dry plasma etch is performed on the first surface 402 to form the voids 502. The dry plasma etch is based on the type of material forming the semiconductor wafer 400. For example, the plasma etch is a chlorine based plasma etch and the feature tool is a parallel plate Reactive Ion Etch apparatus, Inductively Coupled Plasma reactor or, alternatively, an electron cyclotron resonance plasma reactor. In response to the voids 502 being formed, the photoresist layer 504 is removed from the first surface 402 of the semiconductor wafer 400, as shown in a third stage illustrated in FIG. 6.

In some examples, the initial wafer thickness of the semiconductor wafer 400, defined by the distance between the first surface 402 and the second surface 404 is adjusted by back grinding. In a fourth stage, as shown in FIG. 7, a back grinding tape 700 is applied to the second surface 404 of the semiconductor wafer 400. The back grinding tape 700 supports the semiconductor wafer 400 during back grinding. Additionally, the back grinding tape 700 can act as a layer for protecting the second surface 404 of the semiconductor wafer 400 during back grinding. Turning to the fifth stage illustrated in FIG. 8, the first surface 402 of the semiconductor wafer 400 is grinded with a grinding tool 800 to remove material from the first surface 402 forming an adjusted first surface 802. An adjusted wafer thickness is defined as the distance between the adjusted first surface 802 and the second surface 404. The adjusted wafer thickness is less thick than the initial wafer thickness since wafer material is removed. In some examples, the semiconductor wafer 400 is positioned upside down for back grinding.

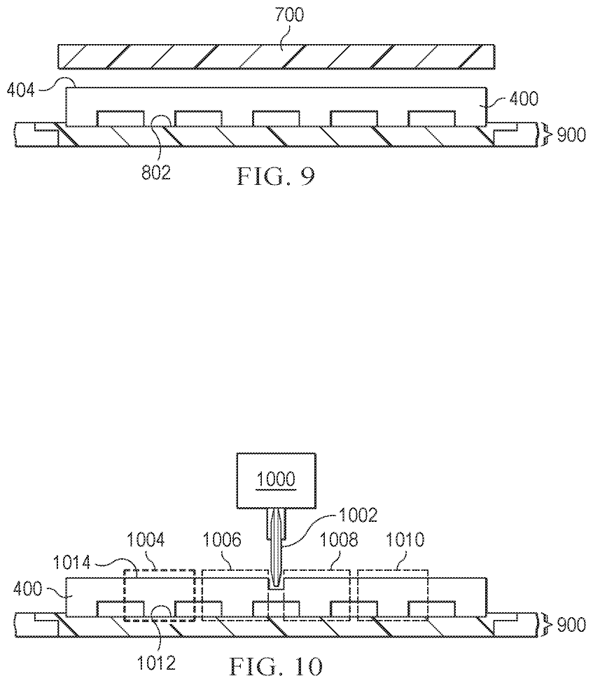

At block 306 of FIG. 3, the method 300 includes affixing the first surface of the semiconductor wafer 400 to a dicing tape 900, for example in a sixth stage shown in FIG. 9. Additionally, in examples, in which the first surface 402 undergoes back grinding, the back grinding tape 700 is removed from the adjusted first surface 802. The dicing tape 900, such as an ultraviolet (UV) tape, is applied to the adjusted first surface 802 of the semiconductor wafer 400. In some examples, the semiconductor wafer 400 with the dicing tape 900 is positioned on a carrier, frame, or other suitable surface. The dicing tape 900 supports the semiconductor wafer 400 during a singulation process. As one example, the dicing tape 900 includes dicing markings that indicate locations where the semiconductor wafer 400 is to be cut during the singulation process.

At block 308 of FIG. 3, the method 300 includes dicing the semiconductor wafer 400 to form a plurality of dies. The singulation process utilizes a severing tool 1000, shown in FIG. 10. For example, the severing tool 1000 is a saw that includes a saw blade 1002 that scribes, saws or dices through a height of the semiconductor wafer 400 in the lateral direction in a seventh stage. The saw blade 1002 travels a path from the second surface 404 to the first surface 402 through the semiconductor wafer 400 to the dicing tape 900 without severing the dicing tape 900. In other examples, the severing tool 1000 is laser-based or plasma-based.

Because the singulation process does not sever the dicing tape 900, a first shaped die 1004, a second shaped die 1006, a third shaped die 1008, and a fourth shaped die 1010 remain supported due to adhesion to the dicing tape 900. The plurality of dies have a base surface 1012 (e.g., the base surface 128 of FIG. 1A, the base surface 214 of FIG. 2A, the base surface 256 of FIG. 2B) and a top surface 1014 (e.g., the top surface 130 of FIG. 1A, the top surface 216 of FIG. 2A, the top surface 258 of FIG. 2B) opposite the base surface 1012. The base surface 1012 corresponds to the first surface 402 or the adjusted first surface 802 of the semiconductor wafer 400 depending on whether back grinding was performed. The top surface 1014 corresponding to the second surface 404.

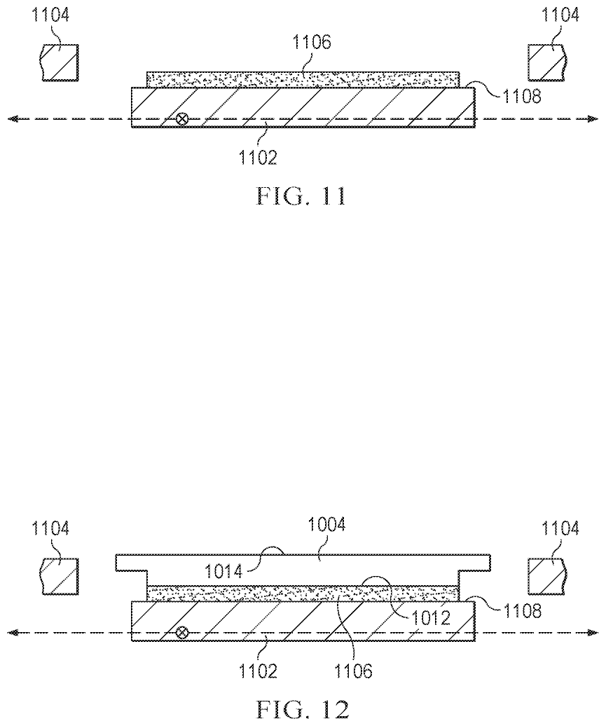

At block 310 of FIG. 3, the method 300 includes mounting the dies to die attach pads of interconnects. For example, an interconnect includes a die attach pad 1102 (die attach pad 102 of FIG. 1A) and a lead 1104 (e.g., the lead 104 of FIG. 1A) as shown in an eighth stage of FIG. 11. The first shaped die 1004 (e.g., the die 108 of FIG. 1A, the die 200 of FIG. 2A, the die of FIG. 2B) is affixed to the die attach pad 1102 with a bond layer 1106 (e.g., the bond layer 106 of FIG. 1A). The bond layer 1106 is applied to at least a portion of the surface region 1108 (e.g., the surface region 114 of FIG. 1A) of the die attach pad 1102. The bond layer 1106 is a filmy adhesive agent, such as an epoxy resin. Turning to a ninth stage shown in FIG. 12, the base surface 1012 of the first shaped die 1004 is affixed to the surface region 1108 with the bond layer 1106.

Although described with respect to first shaped die 1004, other dies, such as the second shaped die 1006, the third shaped die 1008, and the fourth shaped die 1010 are mounted to other dies in a strip using similar packaging techniques described with respect to the eighth stage of FIG. 11 to an eleventh stage shown in FIG. 14. Accordingly, the first shaped die 1004 is mounted to the corresponding die attach pad 1102 with the bond layer 1106.

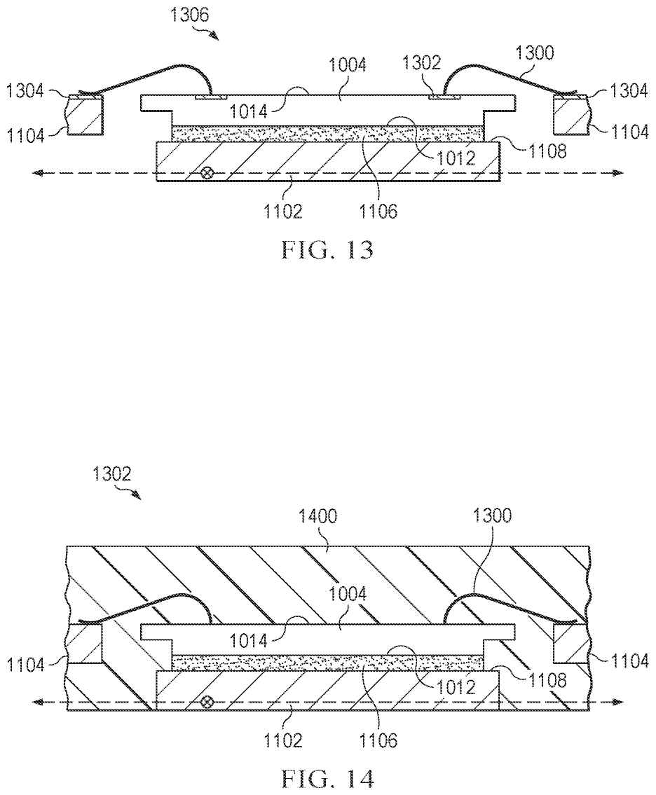

At block 312 of FIG. 3, the method 300 includes attaching bond wires from the die to the lead finger. For example, FIG. 13 shows a bond wire 1300 being attached at the first shaped die 1004 and the lead 1104 resulting in a semiconductor device 1306 (e.g., the semiconductor device 100 of FIG. 1A) in a tenth stage. The bond wire 1300 forms an electrical connection between the first shaped die 1004 and the lead 1104. In some examples, the first shaped die 1004 includes a first bond pad 1302, the lead 1104 defines a second bond pad 1304, and the bond wire 1300 is coupled between the first bond pad 1302 and second bond pad 1304.

At block 314 of FIG. 3, the method 300 includes providing a molding compound to at least partially encapsulate the semiconductor device. For example, FIG. 14 shows the semiconductor device 1306 encapsulated in a molding compound 1400 (e.g., the molding compound 112 of FIG. 1A) in an eleventh stage to form a semiconductor device (e.g., the semiconductor device 100 of FIG. 1A). The molding compound 1400 is formed of one or more insulating material, such as organic resins (e.g., epoxy), inorganic resins, and/or other suitable materials. The molding compound 1400 at least partially encapsulates the first shaped die 1004, and the die attach pad 1102, the lead 1104, and the bond wire 1300.

At block 316 of FIG. 3, the method 300 includes singulating the mounted dies from the strip, such as the mounted die shown in FIG. 13. The top surface 1014 of the first shaped die 1004, opposite the base surface 1012, has a larger surface area then the base surface area of the base surface 1012. Accordingly, the first shaped die 1004 is accommodated by an interconnect with a smaller footprint because the base surface 1012 fits within the footprint while the top surface would not fit within the footprint. Accordingly, rather than requiring a second interconnect, a smaller interconnect can accommodate the first shaped die 1004. Therefore, the shaped dies described herein encourage interconnect sharing, reduce inventory complexity, and simplify fabrication of the semiconductor devices, thereby reducing manufacturing costs.

In this description, unless otherwise stated, “about,” “approximately” or “substantially” preceding a parameter means being within +/−10 percent of that parameter. Modifications are possible in the described embodiments, and other embodiments are possible, within the scope of the claims.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A. The phrase “based on” means “based at least in part on”. Therefore, if X is based on Y, X can be a function of Y and any number of other factors. Modifications are possible in the described embodiments, and other embodiments are possible, within the scope of the claims.

What is claimed is:

1. A device comprising:
a die attach pad having a surface region; and
a die having a base surface that fits within the surface region of the die attach pad and a top surface opposite the base surface, wherein the top surface is larger than the base surface.

2. The device of claim 1, wherein the die further comprises:
a die sidewall includes a base sidewall and an overhang sidewall, wherein the base sidewall extends from the base surface to an overhang surface and the overhang sidewall that extends from the overhang surface to the top surface such that the die sidewall is discontinuous.

3. The device of claim 1, wherein the die further comprises:
a die sidewall includes that extends continuously at an angle from the base surface to the top surface, wherein the angle is relative to the surface region of the die attach pad is less than ninety degrees.

4. The device of claim 1, further comprising:
a lead separated from an edge of the die attach pad in a lateral direction, wherein the edge defines an edge plane and the top surface extends to the edge plane.

5. The device of claim 4 further comprising:
a bond wire attached at the die and the lead; and
a molding compound that encapsulates the bond wire, the lead, the die, and the die attach pad.

6. The device of claim 1, wherein the base surface of the die is affixed to the die attach pad with a bond layer.

7. The device of claim 6, wherein the top surface of the die extends beyond the bond layer.

8. The device of claim 1, further comprising:
a ground line embedded in the die attach pad; and
a ground wire attached at the die and the ground line.

9. A method of forming an integrated circuit (IC) comprising:
providing a semiconductor wafer having a first surface and a second surface opposite the first surface;
etching a number of voids in the first surface of the semiconductor wafer to a first depth;
affixing the first surface of the semiconductor wafer to dicing tape;
dicing the semiconductor wafer to form a plurality of dies, wherein a die of the plurality of dies have a base surface and a top surface opposite the base surface, wherein the top surface has a larger surface area than the base surface;
mounting the dies to die attach pads; and
singulating the mounted dies.

10. The method of claim 9, wherein at least one void of the number of voids has spaced apart die sidewalls that extend toward the second surface approximately orthogonally to the first surface.

11. The method of claim 9, wherein at least one void of the number of voids has spaced apart die sidewalls that are tapered in a direction extending from the first surface and an angle.

12. The method of claim 9, wherein includes a lead separated from an edge of the die attach pad in a lateral direction, wherein the edge defines an edge plane and the top surface extends to the edge plane.

13. The method of claim 12, wherein the top surface of the die includes a first bond pad and the lead defines a second bond pad, the method further comprising:
coupling a bond wire between the first and second bond pads; and
providing molding compound to encapsulate the bond wire, the lead, the die, and the die attach pad.

14. The method of claim 9, wherein the die is mounted to a corresponding die attach pad with a bond layer, and the top surface of the die extends beyond the bond layer.

15. The method of claim 9, further comprising:
embedding a ground line in the die attach pad; and
coupling a ground wire between the die and the ground line.

16. An integrated circuit (IC) package comprising:
a die attach pad having a surface region;
a lead separated from the die attach pad;
a die having a base surface that fits within the surface region of the die attach pad and a top surface opposite the base surface, wherein the top surface is larger than the base surface;
a bond wire attached at the die and the lead; and
a molding compound that encapsulates the bond wire, the lead, the die, and the die attach pad.

17. The IC package of claim 16, wherein the die further comprises:
a die sidewall includes a base sidewall and an overhang sidewall, wherein the base sidewall extends from the base surface to an overhang surface and the overhang sidewall that extends from the overhang surface to the top surface such that the die sidewall is discontinuous.

18. The IC package of claim 16, wherein the die further comprises:
a die sidewall includes that extends continuously at an angle from the base surface to the top surface, wherein the angle is relative to the surface region of the die attach pad is less than ninety degrees.

19. The IC package of claim 16, wherein the lead separated from an edge of the die attach pad in a lateral direction, wherein the edge defines an edge plane and the top surface extends to the edge plane.

20. The IC package of claim 16, wherein the die is mounted to a corresponding die attach pad with a bond layer, and the top surface of the die extends beyond the bond layer.
